(19) United States
(12) Patent Application Publication
(10) Pub. No.: US 2021/0192361 A1
(43) Pub. Date: Jun. 24, 2021

(54) INTELLIGENT DATA OBJECT GENERATION AND ASSIGNMENT USING ARTIFICIAL INTELLIGENCE TECHNIQUES

(71) Applicant: Marriott International, Inc., Bethesda, MD (US)

(72) Inventors: Joern Mumme, Bethesda, MD (US); Eui-Hong Han, Fairfax, VA (US)

(21) Appl. No.: 17/132,486

(22) Filed: Dec. 23, 2020

Related U.S. Application Data
(60) Provisional application No. 62/952,720, filed on Dec. 23, 2019.

(51) Int. Cl. G06N 3/12; G06N 20/20; G06K 9/62; G06F 30/27

(52) U.S. Cl. CPC G06N 3/126; G06N 20/20; G06F 30/27; G06K 9/6228; G06K 9/6218

(57) ABSTRACT

The present disclosure generally relates to systems and methods for intelligently generating and assigning data objects to users. More particularly, the present disclosure relates to systems and methods for executing machine learning models to generate sets of candidate data objects for potentially assigning to users. A final data object is selected from the set of candidate data objects for each user in a manner that maximizes a target objective and satisfies a global constraint.

### CROSS-REFERENCE TO RELATED APPLICATIONS

The present application claims the priority benefit of U.S. Provisional Patent Application No. 62/952,720, filed on Dec. 23, 2019, the disclosure of which is incorporated by reference herein in its entirety for all purposes.

### TECHNICAL FIELD

The present disclosure generally relates to techniques for intelligently generating data objects and assigning the data objects to users in a contextual manner. More particularly, the present disclosure relates to techniques for executing machine-learning models to generate a set of candidate data objects that are specific to a user. A final data object is selected from the set of candidate data objects and assigned to the user in a manner that maximizes a target objective and satisfies a global constraint. The data object that is assigned to the user enables the user to avail one of more resources.

### BACKGROUND

Data objects may be configured to engage users with an entity. In many cases, the data objects are not specific to individual users or groups of users. Even if the data objects are specific to each individual user or group of users, however, generating the variables for each data objects is a technical challenge because two or more variables that define a data object can be co-dependent to some extent. Further, determining the predicted incurred value (e.g., cost) and benefit of the data object, if availed by the user, is technically burdensome at a large scale. In some cases, constraints are not globally imposed on all data objects provided to users, and thus, the incurred value of providing a data object can exceed expectations or become unbounded.

### SUMMARY

As a form of user engagement, an entity may generate a data object, which is defined by a set of one or more variables. For example, a data object may represent an offer to a user that enables the user to avail a resource (e.g., a certificate for a free stay at a hotel). Each variable associated with a data object can represent a feature of the data object. For example, a feature can be a condition that, if satisfied by a user, enables that user to avail a resource (e.g., if the user stays for three nights, the user receives a free night stay). Generating the set of variables that defines data objects and then determining to which users the data objects are assigned, however, is a significant technical challenge, especially when the scale of users reaches Big-Data levels. For example, creating suitably diverse data objects for hundreds of thousands or potentially millions of users is a difficult technical challenge. Further, assigning data objects to users in a manner that is specific or contextual to the individual user at a large scale can be computationally burdensome on processing resources.

Certain aspects and features of the present disclosure relate to enhancing user engagement by intelligently generating and assigning data objects to users. In some implementations, intelligently generating data objects may include generating a set of one or more variables that characterize the data object. For each user of a set of users (e.g., registered users), an object generation system can execute an evolutionary algorithm that automatically generates a set of candidate data objects for the user. Each data object of the set of candidate data objects may be evaluated using an artificial-intelligence model configured to generate an output predictive of the incurred value (e.g., expected cost or liability) and benefit of assigning the data object to the user. Then, for each user, the object generation system selects a final data object from the set of candidate data objects associated with that user. The set of candidate data objects is generated specifically for each user, and thus, the set of candidate data objects generated for one user may differ from the set of candidate data objects generated for another user. Further, intelligently assigning a final data object to a user may include selecting the final data object from the set of candidate data objects in a manner that satisfies a global constraint. The final data object may be selected to maximize a target objective, while satisfying a global constraint that applies to some or all users (e.g., total value incurred by the entity if the final data objects are availed by the users).

Certain aspects and features of the present disclosure include an object assignment system that intelligently generates and assigns data objects to users. The object assignment system may be a network that includes a plurality of components. In some implementations, the object assignment system includes one or more machine-learning models, a resource simulator, an object generation system, and an optimization system. A machine-learning model may be any machine-learning or artificial-intelligence model (e.g., a neural network) trained to predict a dimension of user activity. For example, the machine-learning model may be trained using user data (e.g., previous user behavior, such as any interaction between the user and the entity) and object data (e.g., the variables of data objects that were previously availed by users). Non-limiting examples of a dimension of user activity may include the number of stays a user will complete in a month, the number of nights that a user will stay at a hotel in a given trip, and other suitable dimensions of user activity.

A resource simulator may be a model that combines the one or more machine-learning models to predict a performance indicator for a user and a data object combination. For example, the output of the resource simulator may represent an incurred value (e.g., an amount incurred by an entity if a user avails the resource associated with the data object assigned to the user) and a benefit (e.g., an expected benefit received by the entity if the user avails the data object) predicted to occur if the data object is assigned to the user. In some implementations, the resource simulator is an offline model trained using the historical user data. In other implementations, the resource simulator is an online model that is trained incrementally as new user data is generated.

An object generation system may automatically and intelligently generate a set of candidate data objects for each user of a set of users. The object generation system may execute one or more intelligent search techniques to generate the set of candidate data objects for a particular user or a particular group of users. Non-limiting examples of the intelligent search techniques include evolutionary algorithms, reinforcement learning, genetic algorithms, simulated annealing, random search, and other suitable intelligent search techniques. Further, the object generation system may be configured to communicate with the resource simulator to generate an output predictive of the performance of the data object if the data object were to be assigned to a specific user. The performance of the data object may represent a degree to which the specific user is predicted to avail the data object. The resource simulator may evaluate features associated with the user and the features associated with the data object to predict the performance of the object. A feature of a user may be any information that characterizes a user. A feature of a data object may be any of the variables that define the data object. The performance of a data object may include an expected amount the entity is predicted to receive if the user avails the data object assigned to the user. As another example, the performance of a data object may include a prediction as to whether or not a user will satisfy a condition to receive a benefit (e.g., 10,000 points). The object generation system may evaluate the output of the resource simulator (e.g., the expected incremental benefit of the data object and the expected incurred value of the data object if availed by the user) while executing the intelligent search algorithm to iteratively generate a population of candidate data objects, select a sub-population of data objects, and generate a new population of data objects based on the selected sub-population. The object generation system may generate candidate data objects for each user of the set of users. In some examples, the object generation system may generate the candidate data objects for each user of the set of users in parallel.

An optimization system may be configured to select a final data object from the set of candidate data objects for each user. For example, the optimization system may execute a mixed-integer program to select the final data object for the user. Executing the mixed-integer program may enable the optimization system to select final data objects that maximize a target objective (e.g., a certain revenue threshold), while satisfying a global constraint (e.g., total incurred value). As an illustrative example, the global constraint may be a maximum aggregated incurred value (incurred by the entity) of the data objects assigned to the set of users. The set of candidate data objects for each user may be inputted to the optimization system (e.g., the mixed-integer program), and the output may be a selection of a final data object for each user, such that the final data object is selected to maximize the entity's target objective while ensuring the aggregated incurred value of the final data objects assigned to the users is below a threshold. The optimization system may assign the selected final data object to the user. Assigning the final data object to the user enables the user to avail the resource (e.g., one night stay) associated with the final data object if the user chooses to do so.

Each data object of a given set of candidate data objects is generated for a specific user. However, generating the set of candidate data objects for each user of a large set of users imposes a technical challenge on the servers of the object assignment system. For instance, performing the various iterations of the evolutionary algorithm for the set of users can impose a large processing load on the servers in the aggregate. Therefore, according to certain aspects of the present disclosure, the functioning of the servers of the object assignment system can be improved while still generating data objects for users at scale by clustering users based on user features and then evaluating the data objects against each cluster of users, rather than against each individual user. As part of the evaluation, the object assignment system clusters the users prior to the evaluation of the data object's impact on the user cluster. This clustering before evaluation reduces the number of iterations that have to go through the resource simulator. The data objects are then evaluated at an aggregate level. For example, the evaluation may determine that, for a given cluster of users, the data object is predicted to have a certain performance. After the data object is selected for the cluster of users, the data object is de-aggregated back to the user level, thereby reducing the number of iterations performed for the evolutionary algorithm to generate the set of candidate data objects.

Additionally, as another a technical advantage, the computational efficiency of resource usage, such as the assignment of data objects to users, may be enhanced using machine-learning or artificial intelligence techniques. The automatic and intelligent generation of candidate data objects for a user ensures that a final data object is selected from candidate data objects predicted to be availed by the user. Additionally, resource usage is enhanced because the selection of final data objects for the set of users is performed in a manner that maximizes a target objective, while satisfying a global constraint, thereby preventing a variable, such as the predicted incurred value of a data object assigned to a particular user, from becoming unbounded or excessively large. The automatic generation and intelligent selection of final data objects also enables the entity to assign user-specific data objects to users at a large scale in a computationally efficient manner.

In some implementations, a system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a computer-implemented. The computer-implemented method also includes identifying a plurality of user profiles, each user profile of the plurality of user profiles including one or more user features characterizing a user, and the one or more user features being determined based at least in part on one or more data objects previously availed by the user. The computer-implemented method also includes training one or more machine-learning models to predict a dimension of user behavior, each machine-learning model being trained at least in part on the plurality of user profiles and the one or more data objects previously availed by each user. The computer-implemented method also includes accessing a resource simulator model configured to generating an output predictive of a performance of a data object within a period of time using the one or more machine-learning models. The computer-implemented method also includes automatically generating a seed population of data objects based on a plurality of data object features, each data object of the population of data objects being associated with a constraint variable, and the constraint variable being an output of the resource simulator model; generating a set of candidate data objects for each user profile of the plurality of user profiles, the resource simulator model being executed to select the set of candidate data objects from the seed population of data objects; processing the set of candidate data objects for each user profile of the plurality of user profiles using an optimization model configured to maximize a target objective while satisfying a global constraint. The computer-implemented method also includes in response to the processing, selecting a final data object from the set of candidate data objects for each user profile of the plurality of user profiles, the optimization model being executed to select the final data object for each user profile of the plurality of user profiles so that an aggregation of constraint variables associated with the selected final data objects satisfies the global constraint. The computer-implemented method also includes assigning, for each user profile of the plurality of user profiles, the selected final data object to the user profile, the assignment enabling the user associated with the user profile to avail the final data object. Other embodiments of this aspect include corresponding computer systems, apparatus, and computer programs recorded on one or more computer storage devices, each configured to perform the actions of the methods.

Implementations may include one or more of the following features. The computer-implemented method where generating the candidate set of data objects further includes: executing an evolutionary algorithm, where the execution includes iteratively: evaluating each data object of the seed population using the resource simulator model; selecting a sub-population of data objects from the population of data objects based on a result of evaluating the population of data objects using the resource simulator model; generating a new population based on the selected sub-population of data objects; and generating the set of candidate data objects based on the selected sub-population of data objects. The evolutionary algorithm is a genetic algorithm. Any one or more from the following group are executed to generate the set of candidate objects: an evolutionary algorithm, a reinforcement learning algorithm, a genetic algorithm, a simulated annealing algorithm, and a random search algorithm. The resource simulator model is a combination of two or more trained machine-learning models of the one or more trained machine-learning models, where each trained machine-learning model of the two or more trained machine-learning models is configured to predict the dimension of user behavior as a function of the one or more user features and the plurality of data object features, and where the resource simulator model is trained offline and is used to evaluate each data object of the seed population of data objects. The optimization model is a mixed-integer program that generates the final data object for each user profile of the plurality of user profiles in parallel. The computer-implemented method further including: performing a clustering operation on the plurality of user profiles, the clustering operation being based on the one or more user features included in each user profile of the plurality of user profiles, and the clustering operation forming one or more clusters of user profiles; identifying a centroid of each cluster of the one or more clusters; generating a set of candidate data objects for the centroid of each cluster of the one or more clusters, the set of candidate data objects being generated using an evolutionary algorithm; and selecting a final data object for the centroid of each cluster of the one or more clusters, the final data objects for the one or more clusters satisfying the global constraint. Implementations of the described techniques may include hardware, a method or process, or computer software on a computer-accessible medium.

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings and each claim.

### BRIEF DESCRIPTION OF THE DRAWINGS

The specification makes reference to the following appended figures, in which use of like reference numerals in different figures is intended to illustrate like or analogous components.

FIG. 1 is a block diagram illustrating a network environment for intelligently generating and assigning data objects to users, according to some aspects of the present disclosure.

FIG. 2 is a diagram illustrating a process flow for intelligently generating and assigning data objects to users, according to some aspects of the present disclosure.

FIG. 3 is a diagram illustrating a process flow for intelligently generating candidate data objects for a user, according to some aspects of the present disclosure.

FIG. 4 is a diagram illustrating an example of intelligently assigning a final data object to a user, according to some aspects of the present disclosure.

FIG. 5 is a flowchart illustrating an example of a process for intelligently generating and assigning data objects to users, according to some aspects of the present disclosure.

### DETAILED DESCRIPTION

Entities (e.g., companies) often engage with users by assigning data objects to the users. A data object, as referred to herein, is a digital representation of an offer that an entity assigns to a user to avail. As an illustrative example, an offer may be that a user receives 2000 points for every second hotel stay. The digital representation of the offer is stored in a database as a data object. Further, the data object, as stored in the database, includes one or more variables that define the offer. Continuing with the illustrative example above, one variable of the data object may be 2000 points and another variable may be the frequency of every second night. The data objects that are assigned to the users, however, may not be customized to the unique characteristics of users. Even when data objects are customized, the data objects are often assigned to users without assessing the potential benefit and value that the entity would incur should the data objects be availed by the users. Additionally, generating data objects to users at Big-Data levels is a significant technical challenge, given the excessive burdens on processing resources at such a large scale. Certain aspects and features of the present disclosure enhance the process of generating data objects for users at a large or small scale.

Certain aspects and features of the present disclosure include an object assignment system configured to intelligently generate and assign user-specific data objects to users in a computationally efficient manner using artificial intelligence. The object assignment system may be configured to execute an intelligent search technique that includes interacting with a resource simulator (e.g., an offline machine learning model trained using a data set of user behavior and data object features) to iteratively generate a set of candidate data objects for each user of a set of users. Additionally, the object assignment system may include an optimization system that selects a final data object for each user of the set of users (and potentially re-selects final data objects for certain users) to ensure that the selected final data objects maximize an entity's target objective (e.g., a target threshold of users availing a resource associated with a data object), while satisfying a global constraint (e.g., total number of data objects assigned to users). As an illustrative example, a global constraint may be a maximum incurred value that an entity has allotted for the final data objects assigned to the set of users. The optimization system may execute a mixed-integer program that evaluates the candidate data objects for each user and selects a final data object (which may be sub-optimal for a given user) that maximizes a target objective while nonetheless satisfying the maximum incurred value set by the entity. The final data object assigned to each user may then be available for the user to avail. For example, the object assignment system may transmit a communication (e.g., an email) to a device operated by the user, indicating that the final object is available for the user to avail.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative embodiments but, like the illustrative embodiments, should not be used to limit the present disclosure. The elements included in the illustrations herein may not be drawn to scale.

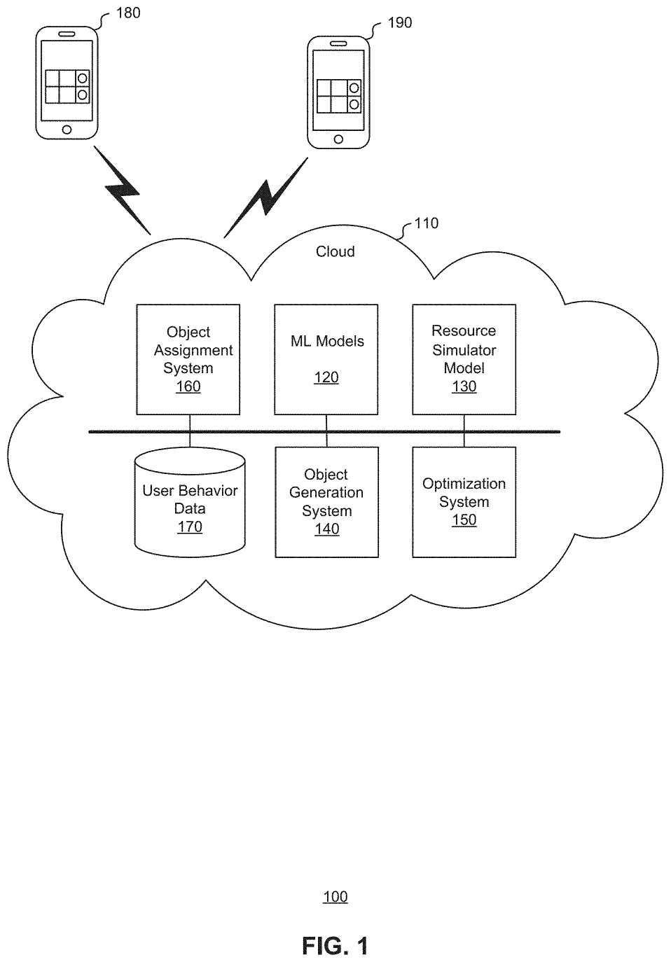

FIG. 1 is a block diagram illustrating a network environment 100 for intelligently generating and assigning data objects to users, according to some aspects of the present disclosure. Network environment 100 may include cloud network 110 associated with an entity, such as a company. User devices, such as user devices 180 and 190, may communicate with cloud network 110. For example, user device 180 may be operated by a user to communicate with an application (e.g., a native mobile application) or webpage provided by the entity associated with the cloud network 110. Similarly, user device 190 may be operated by a user to communicate with the application or webpage. As a non-limiting example, the application may provide a service to the users, such as enabling the users to avail a resource. For example, the application may enable the users to avail a resource associated with a data object assigned to the user by the entity. While FIG. 1 illustrates two smartphones as the user devices 180 and 190, it will be appreciated that any number of user devices may be included in network environment 100, and that the user devices may be any portable computing device (e.g., smartphone, laptop, tablet, etc.) or non-portable computing device (e.g., desktop computer, electronic kiosk, etc.).

In some implementations, cloud network 110 may include several components, for example, object assignment system 160, machine-learning (ML) models 120, resource simulator model 130, user behavior database 170, object generation system 140, and optimization system 150. Object assignment system 160 may include one or more servers storing executable code that, when executed, performs one or more functions relating to assigning data objects to users. Object assignment system 160 may be configured to facilitate the assignment of data objects to users. As an illustrative example, a user may operate user device 180 to communicate with object assignment system 160 to avail a data object that was emailed by object assignment system 160 to an email address associated with the user. User behavior database 170 may store metadata representing interactions between any user devices and any component(s) of cloud network 110. For example, if user device 180 interacts with object assignment system 160 to avail a data object, user behavior database 170 may collect metadata associated with the interaction, including one or more characteristics of the user and/or one or more features of the data object. As another email, if user device 190 selects a link in an email associated with a data object provided by the company, the metadata associated with the selection of the link may be stored in user behavior database 170.

ML models 120 may include a server and/or database that stores one or more trained machine-learning models. For example, ML models 120 may include any trained machine learning or artificial intelligence model, such as a neural network, support vector machine (SVM), decision tree, gradient boosting networks, and other suitable models. Any of the trained models stored in ML models 120 may be trained using the data stored in user behavior database 170. In some implementations, multiple machine-learning models may be stored in ML models 120. Each model may be trained to predict a dimension of user behavior. Non-limiting examples of a dimension of user behavior include the number of times a user stays at a hotel in a month, the number of nights that a user stays, and other suitable dimensions of user behavior. As an illustrative example, the user data (e.g., features of users) and the object data (e.g., variables of data objects) that are stored in user behavior database 170 may be inputted into ML models 120 to train a model (e.g., a neural network). A first feature of a user may be the average number of times the user has stayed at a location each month of the year. A second feature of a user may be the number of nights the user stays at a location during each stay. The user data representing the feature for each user stored in the user behavior database 170 may be inputted into a model to train the model. Training the model may include calculating intermediate values of the nodes of a neural network based on the user data. ML models 120 may include a first model trained using the first feature and a second model trained using the second feature. To illustrate and only as a non-limiting example, a machine-learning model may be a logistic regression model. The learning algorithms of the logistic regression model evaluate the training data, which includes the first feature across a set of users, to generate one or more feature weights for the first feature. A feature weight may represent a correlation between the first feature of the user data for a particular user and an outcome, such as the user behavior of frequency of night stays over a time period. The feature weight may be an intermediate value that is calculated by the logistic regression model. In some examples, the intermediate value(s) can be informative or predictive of future user behavior for the particular user associated with the feature weight.

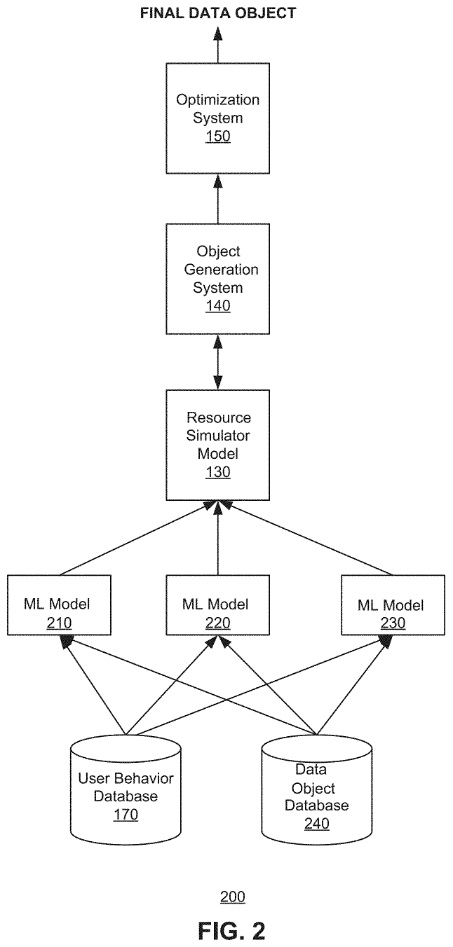

Resource simulator 130 may be a combination of one or more models of ML models 120. In some implementations, resource simulator model 130 may be configured to predict the benefit (e.g., expected incremental received value) and the incurred value of each data object inputted into the resource simulator model 130. In some implementations, resource simulator model 130 may be an offline model or models that are trained to evaluate the indicators for data objects. Non-limiting examples of indicators include user lifetime value, value amounts received by the entity from a user, a number of times a user stays for two or more nights at a location, and other suitable indicators. An indicator may represent a performance of the data object. It will be appreciated that resource simulator model 130 is not limited to being an offline model, in that the training of the model is performed using a static data set. Resource simulator 130 may be an online model that learns incrementally as new user data and new object data is stored in user behavior database 170 or object database 240 (shown in FIG. 2). It will also be appreciated that the output of the resource simulator model 130 may be any indicator, and thus, the present disclosure is not limited to the indicators described above.

Object generation system 140 may be one or more servers and/or one or more databases that are configured to generate a set of candidate data objects for each user of a set of users. In some implementations, object generation system 140 may store a plurality of data object features. A data object feature may represent a characteristic of a valid data object. Object generation system 140 may store one or more rules for generating a valid data object. Further, object generation system 140 may execute an intelligent search technique using the one or more rules for generating valid data objects and the data object features to generate a seed population of data objects, on which the intelligent search technique is executed. The intelligent search technique may generate the set of candidate data objects using, for example, reinforcement learning, evolutionary algorithms, genetic algorithms, simulated annealing, random search, and other suitable intelligent search algorithms. Further, the intelligent search technique may include transmitting each candidate data object to resource simulator model 130 to generate an output predictive of the performance of the data object for a specific user. The intelligent search technique may include iteratively selecting a sub-population of the seed population of data objects. The selection of the sub-population may be based on the output generated by resource simulator model 130 for each data object. In some implementations, object generation system 140 includes a data object validator. The data object validator can store one or more rules that can be executed to evaluate a data object generated by the object generation system 140. The data object validator evaluates each data object to determine whether the variables that define the data object represent a valid data object. The variables of a data object may not be independent from each other, but rather may be dependent on each other. Accordingly, the data object validator executes the one or more rules to determine whether the variables of a data object have dependencies that are valid.

As an illustrative example, object generation system 140 may generate a seed population of data objects for a user based on the rules and the data object features stored within the object generation system 140. The data object validator then validates each data object of the seed population. If the data object validator determines that a data object generated by the object generation system 140 is invalid, then the data object validator may discard the data object. Otherwise, the object generation system 140 may then transmit each valid data object of the seed population of data objects to the resource simulator model 130 to determine the predicted performance of the data object for the user. Determining the predicted performance of the data object may include inputting the data object (and the associated data object features) and the user data associated with the user into the resource simulator model 130. Resource simulator model 130 may generate an output predictive of the performance of the data object. For example, the resource simulator model 130 may generate an output representing an indicator of performance, as a predicted incremental received value and the predicted incurred value associated with the data object. The predicted incremental received value may be the amount that the entity is predicted to receive from the user after the user avails the data object. The predicted incurred value of the data object may be the amount that the entity is predicted to incur if the user avails the object. The predicted incremental received value and the predicted incurred value may be indicative of the performance of the data object. The resource simulator 130 may output an indicator (e.g., a numerical value or a text value) that represents the performance of the data object. In some examples, the output of the resource simulator 130 can be any combination of the predicted incremental received value and the predicted incurred value (e.g., a weighed combination, an average, a summation, a different, etc.). Object generation system 140 may then select a sub-population of data objects from the seed population of data objects (e.g., the top 20% objects based on the predicted performance determined by the resource simulator model 130). Object generation system 140 may execute a crossover mutation technique to generate a new population of candidate data objects based on the sub-population of data objects selected from the seed population of data objects. The data object validator can evaluate each new data object in the new population of data objects to ensure that the crossover mutation technique generated a new set of valid data objects. The data object validator discards any newly generated data objects that the data object validator determines as being invalid. Object generation system 140 may again transmit each valid data object of the new population of candidate data objects to resource simulator model 130 to determine the predicted performance of the data object. Object generation system 140 may select a new sub-population of the new population of data objects based on the predicted performance of the data object. Object generation system 140 may iteratively continue the generation of a population, selection of a sub-population, and generation of a new population until a termination condition is reached (e.g., until five iterations have passed or until the performance of each data object in a population converges to exceed a threshold performance). When the object generator system 140 terminates the iterative process of generating data objects, the remaining data objects may be stored as the final set of candidate data objects for the user. The final data object will be selected from this final set of candidate data objects for the user.

In some implementations, the object generation system 140 performs a clustering operation on the set of users. For example, the set of users (e.g., all registered users) may be clustered using a k-means clustering technique to cluster users based on user features (e.g., historical frequency of staying at hotels, demographic information, etc.). The object generation system 140 can generate a seed population of data objects for each cluster of users (rather than for each individual user). After the final set of candidate data objects is determined, each cluster of users can be de-aggregated so that the final set of candidate data objects is associated with each user of the cluster. This clustering of users and generating of data objects for each user cluster can significantly improve the functioning of servers of the object generation system 140. The clustering of users and the generation of data objects for each cluster reduces the number of iterations that an evolutionary algorithm has to perform to generate the final set of candidate data objects. Thus, the techniques described above can be performed by servers at a Big-Data scale with improved computational efficiency.

It will be appreciated that the selection of the sub-population from the seed population may be based on any suitable technique. Non-limiting examples of criteria used as the basis for selecting data objects for the sub-population include ranking the data objects by performance and selecting a top percentile (e.g., top 20%), selecting data objects to ensure that a threshold level of diversity of data object features exists in the sub-population, and selecting data objects that satisfy any suitable selection condition.

In some implementations, object generation system 140 may perform a clustering operation on a plurality of user profiles. A user profile may store the user features that characterize a user. For example, a user profile may store the behavior data and the object data associated with a user. The clustering operation may be performed based on the user features included in each user profile of the plurality of user profiles. The clustering operation may form one or more clusters of user profiles. Object generation system 140 may identify a centroid of each cluster of the one or more clusters. Further, object generation system may generate a set of candidate data objects for the centroid of each cluster of the one or more clusters. For example, object generation system 140 may execute an evolutionary algorithm using metadata associated with the centroid of each cluster to generate the set of candidate data objects. Object generation system 140 may pass the set of candidate data objects to optimization system 150 to select a final data object for the centroid of each cluster of the one or more clusters. The selected final data object may be assigned to each user included in a cluster of users.

Optimization system 150 may be one or more servers and/or one or more databases configured to select a final data object from the set of candidate data objects generated by object generation system 140. In some implementations, optimization system 150 may include a mixed-integer program that selects the final data object from the set of candidate data objects for each user in a manner that maximizes a target objective defined by the entity, while satisfying a global constraint (also defined by the entity) that applies to the set of users (e.g., a total or maximum incurred value allocated for the final data objects). As an illustrative example, the optimization system 150 may pass the set of candidate data objects and the user data into a global optimization problem (e.g., the mixed-integer-program) to select a final data object that maximizes the predicted incremental received value while satisfying the total or maximum predicted incurred value.

FIG. 2 is a diagram illustrating an example of process flow 200 for intelligently generating and assigning data objects to users, according to some aspects of the present disclosure. Process flow 200 may be performed, at least in part, by any of the components illustrated in FIG. 1. For example, process flow 200 may be performed by one or more components of cloud network 110. Further, process flow 200 may be performed to assign to a user a final data object that is predicted to maximize a target objective defined by the entity and satisfy a global constraint that applies to a set of users (e.g., the final data objects assigned to the set of users is not to exceed a threshold number).

Process flow 200 begins with user behavior database 170 storing metadata associated with interactions between users and any component of cloud network 110. For example, a user may interact with cloud network 110 to access a webpage to use a service, such as availing a resource or data object assigned to a user. The metadata associated with that interaction (e.g., the user identifier, and other data extractable from the interaction) may be stored in user behavior database 170. Data object database 240 may also store metadata associated with user interactions. For example, data object database 240 may store metadata associated with data objects assigned to users and/or data objects availed by users. As an illustrative example, a data object may be assigned to a user. If the user avails the data object within a defined period of time (e.g., within three months), data object database 240 may store metadata associated with the availing of the data object by the user. If the user does not avail the data object, that information may also be stored in data object database 240. For example, metadata associated with availing the data object by the user may include the features of the data object (e.g., a feature being a characteristic of the data object), the date the data object was availed, the location or manner in which the data object was availed (e.g., via phone, via the Internet, in-person, and so on), and other suitable metadata. Each of user behavior database 170 and data object database 240 may store historical interactions between users and cloud network 110 (e.g., historical data over the last ten years). While FIG. 2 illustrates two different databases, it will be appreciated that user behavior database 170 and data object database 240 may be stored in the same database(s).

ML models 210, 220, and 230 may each include machine learning or artificial intelligence models (e.g., neural networks, linear regression models, logistic regression models, decision tree models, etc.) that are trained to generate outputs predictive of a dimension of user behavior. Further, ML models 210, 220, and 230 may be trained using the data sets stored in user behavior database 170 and data object database 240. As an illustrative example, ML model 210 may be a neural network trained to generate an output predictive of the number of nights a user is likely to stay at a hotel during a trip. User behavior database 170 may store the historical data of previous users and the number of nights the previous users stayed at hotels. Data object database 240 may store the historical data of users who have previously availed data objects. The historical data stored in both user behavior database 170 and data object database 240 may be used to train the neural network of ML model 210. The neural network may be trained to generate outputs predictive of the number of nights a particular user is likely to stay at a location during a future trip. ML model 220, on the other hand, may also be trained using the historical data stored in user behavior database 170 and data object database 240, but ML model 220 may be trained to generate outputs predictive of a different dimension of user behavior (e.g., the likelihood the user will use a service). Similarly, ML model 230 may also be trained using the historical data stored in user behavior database 170 and data object database 240, but ML model 230 may be trained to generate outputs predictive of yet a different dimension of user behavior (e.g., the number of trips a user is likely to take during a month). While FIG. 2 shows ML models 210, 220, and 230, it will be appreciated that any number of ML models may be trained to predict dimensions of user behavior.

Resource simulator model 130 may be a simulator configured to generate predictions of indicators for data objects considered for assigning to users. In some implementations, resource simulator model 130 may be an offline artificial-intelligence model that combines ML models 210, 220, and 230 to predict an indicator of a specific data object for a specific user. Non-limiting examples of indicators include profits, user lifetime value, first stay activation, and other suitable indicators of performance. It will be appreciated that, in some implementations, resource simulator model 130 may be an online model that is updated based on incremental new historical data processed by ML models 210, 220, and 230. As an illustrative example, the output generated by resource simulator model 130 may be the predicted incremental received value (e.g., revenue) received by the entity after assigning a specific data object to a specific user and/or the predicted incurred value if the specific user avails the specific data object.

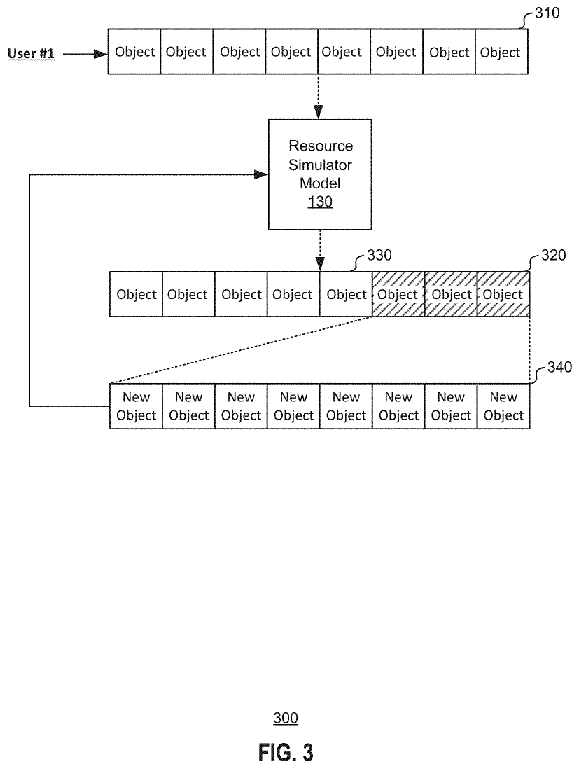

Object generation system 140 may communicate with resource simulator model 130 during the automatic generation of the set of candidate data objects for a user. In some implementations, object generation system 140 may generate a seed population of data objects by evaluating a plurality of data object features using one or more defined rules to randomly generate valid data objects. Object generation system 140 may execute an intelligent search technique and communicate with resource simulator model 130 to predict the performance of each data object of the seed population. As an illustrative example, the intelligent search technique may include generating a seed population of data objects from a plurality of object features (e.g., the number of nights associated with a data object). The intelligent search technique may include executing a genetic algorithm with a fitness function that evaluates a predicted performance (e.g., the performance may be represented an indicator) of each data object from the seed population using resource simulator model 130. The intelligent search technique may also include selecting a group of data objects that performed above a threshold from the seed population and generating a new population of data objects based on the selected group of data objects. The intelligent search process iteratively continues to perform these steps until a termination condition has been reached. The process for generating the set of candidate data objects is described in greater detail with respect to FIG. 3 herein. After object generation system 140 has generated the set of candidate data objects for a specific user, the set of candidate data objects for each user may be passed into optimization system 150.

Optimization system 150 may select a final data object from the set of candidate objects generated for a user. In some implementations, selecting the final data object may include passing the sets of candidate data objects for the users into a mixed-integer program to select a final object that both maximizes a target objective, while satisfying a global constraint. As an illustrative example, the sets of candidate data objects and the user data may be passed from an archive of the object generation system 140 into a global optimization problem, such as the mixed-integer-program, to maximize the target outcome while satisfying the global constraint. The final data object selected by the optimization system 150 may then be assigned to the user.

FIG. 3 is a diagram illustrating an example of a process flow 300 for intelligently generating candidate data objects for a user, according to some aspects of the present disclosure. Process flow 300 may be performed, at least in part, by any component described in FIG. 1 or FIG. 2. For example, process flow 300 may be performed at least in part by object generation system 140 and resource simulator model 130. Further, process flow 300 may be performed to automatically generate a set of candidate data objects for a particular user. The set of candidate data objects generated by process flow 300 may be passed into optimization system 150 for selection of the final object.

Process flow 300 begins, for example, with object generation system 140 generating a seed population of data objects 310 for a specific user or cluster of users (e.g., user #1 as shown in FIG. 3). Object generation system 140 may execute an intelligent search technique using rules that define valid data objects to generate the seed population 310 from a plurality of data object features. The seed population of data objects 310 may be passed into resource simulator model 130 for evaluation. The user features (e.g., the user's age, the user's address, the user's preferences, and any other suitable information characterizing the user) associated with user #1 and the data object features of each data object included in the seed population of data objects 310 may each be input into resource simulator model 130. In some examples, object generation system 140 may retrieve the user features from a user profile associated with user #1. Resource simulator model 130 may evaluate the user features of the user and the object features of each object in the seed population of objects 310. Further, resource simulator model 130 may generate an output for each object of the seed population of data objects 310. The output generated by resource simulator model 130 may represent an indicator of the evaluated data object. For example, an indicator may be a predicted incremental received value resulting from the data object being availed by the user. As another example, an indicator may be a predicted incurred value resulting from the data object being availed by the user.

Object generation system 140 may evaluate the output of the resource simulator model 130 for each data object of the population of data objects 310. The output of the resource simulator model 130 may represent a predicted performance (e.g., the indicator) of the data object if the data object is availed by user #1. Object generation system 140 may select a sub-population 320 of the seed population of data objects 310. As a non-limiting example, object generation system 140 may select data objects for which the indicator (e.g., the output of the resource simulator model 130) is within the top 20% of the population of data objects 310. In this example, object generation system 140 may select sub-population 320 and may disregard sub-population 330. In some implementations, object generation system 140 may then input the selected sub-population 320 into a genetic algorithm to generate a new population of objects 340. The new population of data objects 340 may be generated based on the data object features of the selected sub-population 320 of data objects. For example, the new population of data objects 340 may be generated by object generation system 140 performing a crossover mutation using the genetic algorithm. It will be appreciated that any suitable technique may be implemented to select the sub-population of data objects. For example, the sub-population of data objects may be selected from a population of data objects to ensure a suitable diversity of data object features. In some examples, each instance the object generation system 140 generates a population of data objects (e.g., the original seed population or the new population), the data object validator included in the object generation system 140 may execute one or more rules to validate each newly generated data object. In other examples, the data object validator may only evaluate the final set of candidate data objects to reduce the operations performed by the object generation system 140, thereby reducing the processing load imposed on the servers.

The new population of data objects 340 may be transmitted to resource simulator model 130 for evaluation. Resource simulator model 130 may evaluate each new data object of the new population of data objects 340 and the user features of user #1 to generate one or more indicators for each new data object. Object generation system 140 may evaluate the output of resource simulator model 130 for each new data object. Further, object generation system 140 may select a sub-population of the new data objects of the new population of objects 340 based on the performance of the new data objects or based on other factors (e.g., in the case of a random selection of data objects, or a selection of data objects to enhance the diversity of data objects included in the selected sub-population). As a non-limiting example, object generation system 140 may select new data objects for which the indicator (e.g., the output of the resource simulator model 130) is within the top 20% of the new population of objects 340. The present disclosure is not limited to this example. Process flow 300 may continue to generate and evaluate (e.g., validate) data objects in an iterative manner until the termination condition is satisfied. When the termination condition is satisfied, the remaining new data objects may be the set of candidate data objects that are generated specifically for the user. Non-limiting examples of the termination condition may include terminating the iterative performance of process flow 300 when the performance of some or all of the newly generated data objects are above a certain threshold, terminating the iterative performance of process flow 300 after a threshold number of iterations have be performed, terminating the iterative performance of process flow 300 after a diversity threshold of data objects has been reached, and any other suitable condition.

The iterative performance of process flow 300 may include the generation of a population of data objects, the validation of each data object of the population (e.g., by data object validator), the evaluation of each data object of the population of data objects and the user features of user #1 (or user cluster #1) using resource simulator model 130, the selection of a sub-population of data objects based on the output of the resource simulator model 130, the generation of a new population of data objects based on the selected sub-population of data objects, potentially the validation of each new data object in the new population, the evaluation of each new data object of the new population and the user features using resource simulator model 130, and so on, until the termination condition is satisfied. The remaining data objects when the termination condition is satisfied may be the final set of candidate data objects that are generated specifically for the user. While the intelligent search technique described with respect to FIG. 3 executes a genetic algorithm to generate the set of candidate data objects, it will be appreciated that the present disclosure is not limited thereto. For example, in addition to or in lieu of executing a genetic algorithm to generate the set of candidate data objects, object generation system 140 may generate the set of candidate data objects by executing an evolutionary algorithm, reinforcement learning techniques, simulated annealing techniques, random forest search techniques, and other suitable intelligent search techniques.

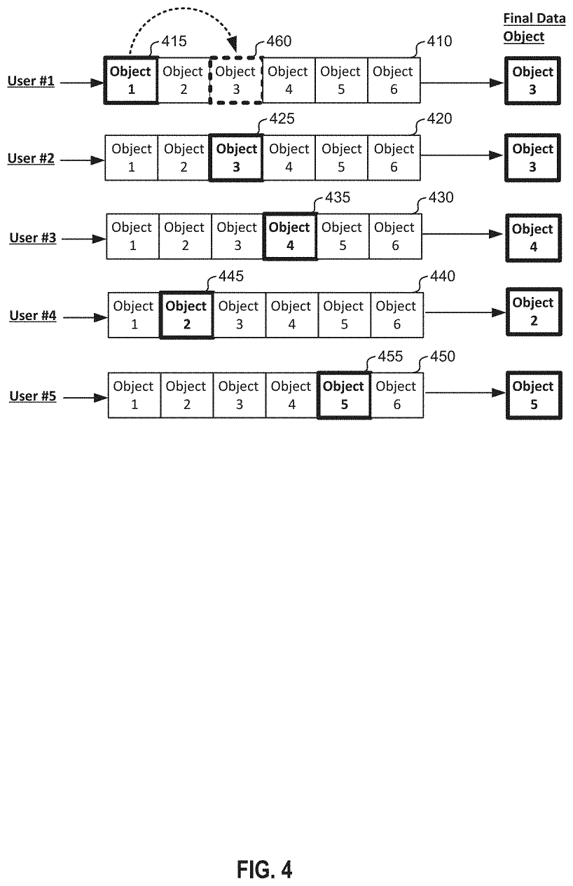

FIG. 4 is a diagram illustrating an example of intelligently assigning a final data object to a user, according to some aspects of the present disclosure. As illustrated in FIG. 4, object generation system 140 generated the set of candidate data objects 410 for user #1, the set of candidate data objects 420 for user #2, the set of candidate data objects 430 for user #3, the set of candidate data objects 440 for user #4, and the set of candidate data objects 450 for user #5. It will be appreciated that object generation system 140 may generate a set of candidate data objects for each of any number of users. It will also be appreciated that, while FIG. 4 illustrates each set of candidate data objects as including data objects 1 through 6, the data objects included in the set of candidate data objects may differ across users. For example, the data objects included in the set of candidate data objects 410 may be partially or entirely different from the data objects included in the set of candidate data objects 420. Additionally, it will be appreciated that, while FIG. 4 illustrates each set of candidate data objects as including data objects 1 through 6, the set of candidate data objects for a given user may include any number of data objects and the number of candidate data objects may differ across various users. For example, the set of candidate data objects 410 for user #1 may include six data objects, whereas, the set of candidate data objects 420 for user #2 may include ten data objects.

Each set of candidate data objects 410, 420, 430, 440, and 450 may be stored in an archive or database associated with object generation system 140. For example, an archive may be a data structure within or accessible by object generation system 140. Object generation system 140 may pass each set of candidate data objects 410, 420, 430, 440, and 450 into optimization system 150 in parallel or sequentially. In some implementations, optimization system 150 may be configured to execute a mixed-integer program that evaluates the set of candidate data objects for each user and selects a final data object to assign to the user. Optimization system 150 may select a final data object for each user, such that the selected final data object maximizes a target objective (e.g., maximizes the entity's predicted received values from users availing the data object), while at the same time satisfying a global constraint that applies to some or all assigned data objects (e.g., a total or maximum value incurred by the entity if the data objects are availed by users). The incurred value may be predicted based on the variables that define a given data object. For example, a night stay may be associated with a known incurred value.

As an illustrative example, optimization system 150 evaluates the set of candidate data objects 410, 420, 430, 440, and 450 to select the final data objects. Optimization system 150 may select “Data Object 1” 415 for user #1; “Data Object 3” 425 for user #2; “Data Object 4” 435 for user #3; “Data Object 2” 445 for user #4; and “Data Object 5” 455 for user #5 as final data objects. After the final data objects are selected or during the selection of the final data objects, however, optimization system 150 may determine that “Data Object 1” 415 does not maximize the target objective. In another example, optimization system 150 may determine that “Data Object 1” 415 causes the selected final data objects to exceed the global constraint. In yet another example, “Data Object 1” 415 may be the data object with the highest predicted indicator for user #1 (or for user cluster #1). Optimization system 150 may change the selection of “Data Object 1” 415 as the final data object to another data object from the set of candidate data objects 410, despite, for example, “Data Object 1” 415 being the expected best performing data object. Optimization system 150 evaluates the remaining data objects in the set of candidate data objects 410 and changes the selection of the final data object to “Data Object 3” 460. Changing the final data object for user #1 to “Data Object 3” 460 maximizes the target objective and satisfies the global constraint. The final data objects selected by optimization system 150 are assigned to the respective users.

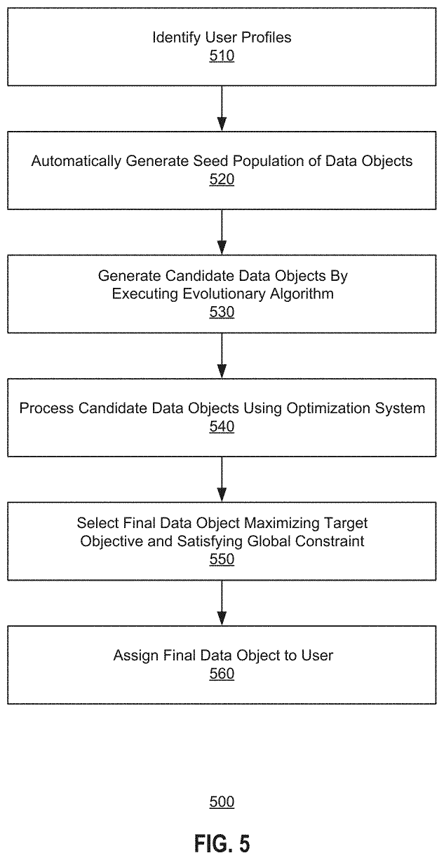

FIG. 5 is a flowchart illustrating an example of a process 500 for intelligently generating and assigning data objects to users, according to some aspects of the present disclosure. Process 500 may be performed, at least in part, by any component described in FIG. 1 or FIG. 2. For example, process 500 may be performed at least in part by object generation system 140, resource simulator model 130, and/or optimization system 150. Further, process 500 may be performed to intelligently generate and select a final data object from a set of candidate data objects specifically for a particular user.

Process 500 begins at block 510 where, for example, the object generation system 140 identifies a set of user profiles for which a final data object is to be selected. For example, the user profiles may be defined by the users of the entity associated with cloud network 110. The user profiles may be stored at user behavior database 170, data object database 240, or any other database within or accessible by cloud network 110. It will be appreciated that any component of cloud network 110 may identify the user profiles for which a final data object is to be selected, at block 510. A user profile may include one or more user features that characterize at least one aspect of the associated user. For example, a user feature may include the age of the user, the preferences of the user (e.g., preference for queen bed or suite), and other suitable features that characterize the user. The user features may be extracted directly from an interaction between the user and a component of the cloud network 110 or may be generated based on existing information stored within cloud network 110.

At block 520, object generation system 140 may evaluate one or more rules for generating valid data objects and a plurality of data object features to automatically generate a seed population of data objects. In some implementations, the seed population of data objects may be randomly generated based on a pseudo-random technique.

At block 530, object generation system 140 may generate a set of candidate data objects for each user identified with a user profile at block 510, using a genetic algorithm, for example. The set of candidate data objects may be generated using an intelligent search algorithm, such as an evolutionary algorithm, a genetic algorithm, a reinforcement learning algorithm, a simulated annealing algorithm, a random search algorithm, and other suitable intelligent search algorithms. An example of generating the set of candidate data objects is described with respect to FIG. 3.

At block 540, the set of candidate data objects for each user may be passed into optimization system 150 for processing. In some implementations, optimization system 150 may execute a mixed-integer program that selects a final data object for each user from the set of candidate data objects that corresponds to the user. The mixed-integer program selects a final data object for each user that maximizes a target objective while satisfying a global constraint that restricts the selection of the final objects for some or all of the users, so that any combination of final data objects satisfies the global constraint.

At block 550, optimization system 150 selects a final data object for each user. It will be appreciated that optimization system 150 may select a final data object that is different from the expected best performing data object for a user to ensure the global constraint is satisfied. For example, if an initial selection of a final data object is made for a user, and then the final data objects are selected for other users, the initial selection of the final data object may no longer satisfy the global constraint. In this case, optimization system 150 can select another object from the corresponding set of candidate objects, such that a target objective is maximized and a global constraint is satisfied. At block 560, the selected final data object may be assigned to the user. Assigning a final data object to a user enables that user to avail the final data object. For example, object assignment system 160 may transmit an email to an email address of the user with the assigned final data object.

The foregoing description of the embodiments, including illustrated embodiments, has been presented only for the purpose of illustration and description and is not intended to be exhaustive or limiting to the precise forms disclosed. Numerous modifications, adaptations, and uses thereof will be apparent to those skilled in the art.

What is claimed is:

1. A computer-implemented method comprising:
identifying a plurality of user profiles, each user profile of the plurality of user profiles including one or more user features characterizing a user, and the one or more user features being determined based at least in part on one or more data objects previously availed by the user;
training one or more machine-learning models to predict a dimension of user behavior, each machine-learning model being trained at least in part on the plurality of user profiles and the one or more data objects previously availed by each user;
accessing a resource simulator model configured to generating an output predictive of a performance of a data object within a period of time using the one or more machine-learning models;
automatically generating a seed population of data objects based on a plurality of data object features, each data object of the population of data objects being associated with a constraint variable, and the constraint variable being an output of the resource simulator model;
generating a set of candidate data objects for each user profile of the plurality of user profiles, the resource simulator model being executed to select the set of candidate data objects from the seed population of data objects;
processing the set of candidate data objects for each user profile of the plurality of user profiles using an optimization model configured to maximize a target objective while satisfying a global constraint;
in response to the processing, selecting a final data object from the set of candidate data objects for each user profile of the plurality of user profiles, the optimization model being executed to select the final data object for each user profile of the plurality of user profiles so that an aggregation of constraint variables associated with the selected final data objects satisfies the global constraint; and
assigning, for each user profile of the plurality of user profiles, the selected final data object to the user profile, the assignment enabling the user associated with the user profile to avail the final data object.

2. The computer-implemented method of claim 1, wherein generating the candidate set of data objects further includes:
executing an evolutionary algorithm, wherein the execution includes iteratively:
evaluating each data object of the seed population using the resource simulator model;
selecting a sub-population of data objects from the population of data objects based on a result of evaluating the population of data objects using the resource simulator model;
generating a new population based on the selected sub-population of data objects; and
generating the set of candidate data objects based on the selected sub-population of data objects.

3. The computer-implemented method of claim 2, wherein the evolutionary algorithm is a genetic algorithm.

4. The computer-implemented method of claim 1, wherein any one or more from the following group are executed to generate the set of candidate objects: an evolutionary algorithm, a reinforcement learning algorithm, a genetic algorithm, a simulated annealing algorithm, and a random search algorithm.

5. The computer-implemented method of claim 1, wherein the resource simulator model is a combination of two or more trained machine-learning models of the one or more trained machine-learning models, wherein each trained machine-learning model of the two or more trained machine-learning models is configured to predict the dimension of user behavior as a function of the one or more user features and the plurality of data object features, and wherein the resource simulator model is trained offline and is used to evaluate each data object of the seed population of data objects.

6. The computer-implemented method of claim 1, wherein the optimization model is a mixed-integer program that generates the final data object for each user profile of the plurality of user profiles in parallel.

7. The computer-implemented method of claim 1, further comprising:
performing a clustering operation on the plurality of user profiles, the clustering operation being based on the one or more user features included in each user profile of the plurality of user profiles, and the clustering operation forming one or more clusters of user profiles;
identifying a centroid of each cluster of the one or more clusters;
generating a set of candidate data objects for the centroid of each cluster of the one or more clusters, the set of candidate data objects being generated using an evolutionary algorithm; and
selecting a final data object for the centroid of each cluster of the one or more clusters, the final data objects for the one or more clusters satisfying the global constraint.

8. A system, comprising:
one or more processors; and
a non-transitory computer-readable storage medium containing instructions which, when executed on the one or more processors, cause the one or more processors to perform operations including:
identifying a plurality of user profiles, each user profile of the plurality of user profiles including one or more user features characterizing a user, and the one or more user features being determined based at least in part on one or more data objects previously availed by the user;
training one or more machine-learning models to predict a dimension of user behavior, each machine-learning model being trained at least in part on the plurality of user profiles and the one or more data objects previously availed by each user;
accessing a resource simulator model configured to generating an output predictive of a performance of a data object within a period of time using the one or more machine-learning models;
automatically generating a seed population of data objects based on a plurality of data object features, each data object of the population of data objects being associated with a constraint variable, and the constraint variable being an output of the resource simulator model;
generating a set of candidate data objects for each user profile of the plurality of user profiles, the resource simulator model being executed to select the set of candidate data objects from the seed population of data objects;
processing the set of candidate data objects for each user profile of the plurality of user profiles using an optimization model configured to maximize a target objective while satisfying a global constraint;
in response to the processing, selecting a final data object from the set of candidate data objects for each user profile of the plurality of user profiles, the optimization model being executed to select the final data object for each user profile of the plurality of user profiles so that an aggregation of constraint variables associated with the selected final data objects satisfies the global constraint; and
assigning, for each user profile of the plurality of user profiles, the selected final data object to the user profile, the assignment enabling the user associated with the user profile to avail the final data object.

9. The system of claim 8, wherein the operation of generating the candidate set of data objects further comprises:
executing an evolutionary algorithm, wherein the execution includes iteratively:
evaluating each data object of the seed population using the resource simulator model;
selecting a sub-population of data objects from the population of data objects based on a result of evaluating the population of data objects using the resource simulator model;
generating a new population based on the selected sub-population of data objects; and
generating the set of candidate data objects based on the selected sub-population of data objects.

10. The system of claim 9, wherein the evolutionary algorithm is a genetic algorithm.

11. The system of claim 8, wherein any one or more from the following group are executed to generate the set of candidate objects: an evolutionary algorithm, a reinforcement learning algorithm, a genetic algorithm, a simulated annealing algorithm, and a random search algorithm.

12. The system of claim 8, wherein the resource simulator model is a combination of two or more trained machine-learning models of the one or more trained machine-learning models, wherein each trained machine-learning model of the two or more trained machine-learning models is configured to predict the dimension of user behavior as a function of the one or more user features and the plurality of data object features, and wherein the resource simulator model is trained offline and is used to evaluate each data object of the seed population of data objects.

13. The system of claim 8, wherein the optimization model is a mixed-integer program that generates the final data object for each user profile of the plurality of user profiles in parallel.

14. The system of claim 8, wherein the operations further comprise:
performing a clustering operation on the plurality of user profiles, the clustering operation being based on the one or more user features included in each user profile of the plurality of user profiles, and the clustering operation forming one or more clusters of user profiles;
identifying a centroid of each cluster of the one or more clusters;
generating a set of candidate data objects for the centroid of each cluster of the one or more clusters, the set of candidate data objects being generated using an evolutionary algorithm; and
selecting a final data object for the centroid of each cluster of the one or more clusters, the final data objects for the one or more clusters satisfying the global constraint.

15. A computer-program product tangibly embodied in a non-transitory machine-readable storage medium, including instructions configured to cause a processing apparatus to perform operations including:
identifying a plurality of user profiles, each user profile of the plurality of user profiles including one or more user features characterizing a user, and the one or more user features being determined based at least in part on one or more data objects previously availed by the user;
training one or more machine-learning models to predict a dimension of user behavior, each machine-learning model being trained at least in part on the plurality of user profiles and the one or more data objects previously availed by each user;
accessing a resource simulator model configured to generating an output predictive of a performance of a data object within a period of time using the one or more machine-learning models;
automatically generating a seed population of data objects based on a plurality of data object features, each data object of the population of data objects being associated with a constraint variable, and the constraint variable being an output of the resource simulator model;
generating a set of candidate data objects for each user profile of the plurality of user profiles, the resource simulator model being executed to select the set of candidate data objects from the seed population of data objects;
processing the set of candidate data objects for each user profile of the plurality of user profiles using an optimization model configured to maximize a target objective while satisfying a global constraint;
in response to the processing, selecting a final data object from the set of candidate data objects for each user profile of the plurality of user profiles, the optimization model being executed to select the final data object for each user profile of the plurality of user profiles so that an aggregation of constraint variables associated with the selected final data objects satisfies the global constraint; and
assigning, for each user profile of the plurality of user profiles, the selected final data object to the user profile, the assignment enabling the user associated with the user profile to avail the final data object.

16. The computer-program product of claim 15, wherein the operation of generating the candidate set of data objects further comprises:
executing an evolutionary algorithm, wherein the execution includes iteratively:
evaluating each data object of the seed population using the resource simulator model;
selecting a sub-population of data objects from the population of data objects based on a result of evaluating the population of data objects using the resource simulator model;
generating a new population based on the selected sub-population of data objects; and
generating the set of candidate data objects based on the selected sub-population of data objects.

17. The computer-program product of claim 16, wherein the evolutionary algorithm is a genetic algorithm.

18. The computer-program product of claim 15, wherein any one or more from the following group are executed to generate the set of candidate objects: an evolutionary algorithm, a reinforcement learning algorithm, a genetic algorithm, a simulated annealing algorithm, and a random search algorithm.

19. The computer-program product of claim 15, wherein the resource simulator model is a combination of two or more trained machine-learning models of the one or more trained machine-learning models, wherein each trained machine-learning model of the two or more trained machine-learning models is configured to predict the dimension of user behavior as a function of the one or more user features and the plurality of data object features, and wherein the resource simulator model is trained offline and is used to evaluate each data object of the seed population of data objects.

20. The computer-program product of claim 15, wherein the optimization model is a mixed-integer program that generates the final data object for each user profile of the plurality of user profiles in parallel.
